(19) United States
(12) Patent Application Publication
(10) Pub. No.: US 2025/0391646 A1
(43) Pub. Date: Dec. 25, 2025

(54) PLASMA PROCESSING APPARATUS AND PLASMA PROCESSING METHOD

(71) Applicant: Panasonic Intellectual Property Management Co., Ltd., Osaka (JP)

(72) Inventors: Toshiyuki TAKASAKI, OSAKA (JP); Hisao NAGAI, OSAKA (JP); Hidehiko KARASAKI, HYOGO (JP); Shogo OKITA, HYOGO (JP)

(21) Appl. No.: 19/240,213

(22) Filed: Jun. 17, 2025

(30) Foreign Application Priority Data
Jun. 19, 2024 (JP) 2024-098886

(51) Int. Cl. H01J 37/32

(52) U.S. Cl. CPC H01J 37/3288; H01J 37/32724; H01J 2237/334

(57) ABSTRACT

A disclosed plasma processing apparatus includes a chamber having an opening, a plasma generation section that generates plasma in the chamber, a light-transmitting member that blocks at least a part of the opening and that transmits infrared rays, a stage that is provided in the chamber and on which the substrate is to be placed, and a sensor that receives the infrared rays emitted from the stage or the substrate placed on the stage through the light-transmitting member and outputs a measurement value corresponding to the intensity of the received infrared rays, and a determination section. The determination section determines whether or not maintenance of the light-transmitting member is necessary based on the measurement value.

### CROSS REFERENCE TO RELATED APPLICATION

The present application is based on and claims priority under 35 U.S.C. § 119 with respect to the Japanese Patent Application No. 2024-098886, filed on Jun. 19, 2024, of which entire content is incorporated herein by reference into the present application.

### TECHNICAL FIELD

The present disclosure relates to a plasma processing apparatus and a plasma processing method.

### BACKGROUND

Conventionally, plasma processing apparatuses have been known that perform plasma processing on an object to be processed such as a substrate (e.g., Japanese Laid-Open Patent Publication No. 2018-006758). Japanese Laid-Open Patent Publication No. 2018-006758 discloses “a plasma dicing apparatus including: a chamber; a substrate support section for supporting a non-metal substrate of a type having a dicing lane; a plasma generator for generating in the chamber plasma suitable for plasma etching on the substrate along the dicing lane; an infrared detector for monitoring the infrared rays emitted from at least a part of the dicing lane; and a state detector configured to detect the state associated with the final stage of a plasma dicing process from the monitored infrared rays.

Some plasma processing apparatuses have a configuration in which the infrared rays emitted from a substrate or the like are made incident on a sensor through a light-transmitting member (e.g., a window that allows infrared rays to pass through). However, once a product associated with the plasma processing is deposited on the light-transmitting member, it becomes difficult to accurately detect the temperature of the substrate by using the sensor because a part of the infrared rays is blocked in the light-transmitting member, for example. When the light-transmitting member is contaminated with a deposit that exceeds a certain level, it is necessary to perform maintenance of the light-transmitting member (e.g., removal of the contaminant or replacement with a new light-transmitting member). Therefore, it is desired to develop a technique for appropriately determining whether or not maintenance is necessary. Under such circumstances, one of the objects of the present disclosure is to determine whether or not maintenance of the light-transmitting member is necessary due to contamination.

### SUMMARY

One aspect of the present disclosure relates to a plasma processing apparatus. The plasma processing apparatus includes: a chamber having an opening; a plasma generation section that generates plasma in the chamber; a light-transmitting member that blocks at least a part of the opening and that transmits infrared rays; a stage that is provided in the chamber and on which a substrate is to be placed; a sensor that receives infrared rays emitted from the stage or the substrate placed on the stage through the light-transmitting member and outputs a measurement value corresponding to an intensity of the received infrared rays; and a determination section that determines whether or not maintenance of the light-transmitting member is necessary based on the measurement value.

Another aspect of the present disclosure relates to a plasma processing method. The plasma processing method is a method carried out by a plasma processing apparatus including: a chamber having an opening; a plasma generation section that generates plasma in the chamber; a light-transmitting member that blocks at least a part of the opening and that transmits infrared rays; a stage that is provided in the chamber and on which a substrate is to be placed; and a sensor that receives infrared rays emitted from the stage or the substrate placed on the stage through the light-transmitting member and outputs a measurement value corresponding to an intensity of the received infrared rays, the method including a determination step of determining whether or not maintenance of the light-transmitting member is necessary based on the measurement value.

### BRIEF DESCRIPTION OF DRAWINGS

FIG. 1 is a schematic cross-sectional view of an example of a plasma processing apparatus according to the present disclosure.

FIG. 2 is a graph showing examples of the measurement values of a sensor before and after a start of plasma processing, wherein the solid line indicates measurement value when using a new dielectric window, and the broken line indicates measurement value when using a contaminated dielectric window.

FIG. 3 is a flowchart depicting a plasma processing method of a first embodiment.

FIG. 4 is a flowchart depicting a plasma processing method of a second embodiment.

FIG. 5 is a graph showing examples of measurement values of the sensor during the plasma processing, wherein the solid line indicates measurement value, and the broken line indicates estimated value on the assumption that plasma was not generated.

FIG. 6 is a flowchart depicting a plasma processing method of a third embodiment.

### DETAILED DESCRIPTION

Embodiments of a plasma processing apparatus and a plasma processing method according to the present disclosure will be described below. However, the present disclosure is not limited to the examples described below. In the following description, specific numerical values and materials may be exemplified in some cases, but other numerical values and other materials may be adopted as long as the effects of the present disclosure can be obtained.

### (Plasma Processing Apparatus)

The plasma processing apparatus according to the present disclosure is an apparatus for performing plasma processing on a substrate as an object to be processed. The plasma processing apparatus may be, for example, a plasma etching apparatus, a plasma dicer, a plasma ashing apparatus, or a plasma CVD apparatus. The plasma processing apparatus includes a chamber, a plasma generation section, a light-transmitting member, a stage, a sensor, and a determination section.

The chamber has an opening. The opening may be located at the top of the chamber. The opening may be open upward. The chamber may be formed in a hollow cylindrical shape. The chamber may be constituted of a metal and may be grounded.

The plasma generation section generates plasma in the chamber. The plasma generation section may include at least one induction coil and at least one high-frequency power supply that supplies high-frequency power to the at least one induction coil.

The light-transmitting member blocks at least a part of the opening of the chamber and transmits infrared rays. The light-transmitting member may transmit 90% or more of incident infrared rays. The light-transmitting member may be constituted of a dielectric material, for example. The shape of the light-transmitting member is not particularly limited, and may be a disk shape, for example.

The stage is provided in the chamber, and the substrate is to be placed thereon. The stage may have a horizontal placement surface on which the substrate is to be placed. The stage may have a flow path through which a refrigerant for cooling the substrate flows during the plasma processing. The stage may include an electrostatic chuck mechanism for chucking the substrate. The stage may have a lower electrode to which high-frequency power is applied. The substrate may be a semiconductor substrate that is singulated by plasma etching, for example. The semiconductor substrate has a plurality of element regions and a division region defining the element regions. The element regions each include a semiconductor layer and a wiring layer, for example. By etching the division region, element chips each including the semiconductor layer and the wiring layer can be obtained. The substrate may be placed on the stage with it supported by a carrier. The carrier may be a resin sheet whose outer periphery is held by a frame, for example.

The sensor receives the infrared rays emitted from the stage or the substrate placed on the stage through the light-transmitting member. The sensor outputs a measurement value corresponding to the intensity of the received infrared rays. The mode of outputting the measurement value is not particularly limited, and a voltage having a magnitude corresponding to the intensity of the received infrared rays may be output, for example. The intensity of the infrared rays emitted from the stage or the substrate can increase as the temperature of the stage or the substrate is increased.

The determination section determines whether or not maintenance of the light-transmitting member is necessary based on the measurement value output by the sensor. As described above, the sensor receives infrared rays through the light-transmitting member. Therefore, when the light-transmitting member is contaminated by more than a specific degree, for example, the intensity of the infrared rays received by the sensor can greatly change as compared with a case where the light-transmitting member is not so contaminated. As such intensity change increases, it becomes difficult to appropriately control the plasma processing apparatus based on the measurement value of the sensor. In view of the foregoing, for example, the measurement value of the sensor may be compared with a predetermined threshold value to detect an excessively large change in the measurement value, that is, in the intensity of the infrared rays received by the sensor, and it may be determined that maintenance of the light-transmitting member is necessary when such an excessively large change is detected. By performing maintenance of the light-transmitting member in response to such determination, appropriate plasma processing can be continued. As another example, it is conceivable that information on a measurement value (hereinafter, referred to as first measurement value) of the sensor when the light-transmitting member is not contaminated is prestored in the determination section and it is determined that maintenance of the light-transmitting member is necessary when a difference between the first measurement value and the measurement value of the sensor exceeds a predetermined value. Note that the “maintenance” in the present specification includes at least removal of a contaminant adhering to the light-transmitting member by any method and replacement of the contaminated light-transmitting member with a new light-transmitting member.

The determination section may determine whether or not maintenance of the light-transmitting member is necessary based on a measurement value acquired when no plasma is generated in the chamber. As a result of intensive research, it has been found that due to contamination of the light-transmitting member, the measurement value output by the sensor more greatly changes in a low-temperature state (e.g., a state in which no plasma generation is generated in the chamber) than in a high-temperature state (e.g., a state in which plasma is generated in the chamber). In view of the foregoing, in the present configuration, whether or not maintenance of the light-transmitting member is necessary is determined based on a measurement value in a state in which such a change in the measurement value is large, that is, in a state of no plasma generation in the chamber. Thus, it is possible to further easily determine whether or not maintenance of the light-transmitting member is necessary.

The determination section may determine whether or not maintenance of the light-transmitting member is necessary based on a measurement value acquired when no substrate is placed on the stage. In other words, the determination section may determine whether or not maintenance of the light-transmitting member is necessary based on a measurement value output by the sensor that has received the infrared rays emitted from the stage. In this case, whether or not maintenance of the light-transmitting member is necessary can be easily determined by the plasma processing apparatus alone.

The determination section may determine whether or not maintenance of the light-transmitting member is necessary based on a measurement value acquired when the substrate is placed on the stage. In other words, the determination section may determine whether or not maintenance of the light-transmitting member is necessary based on a measurement value output by the sensor that has received the infrared rays emitted from the substrate placed on the stage. In this case, for example, preparation of a substrate particularly suitable for determining whether or not maintenance of the light-transmitting member is necessary makes it possible to improve determination accuracy. Note that the substrate may be a substrate that is a target for plasma processing or a substrate that is not a target for plasma processing.

The determination section may determine whether or not maintenance of the light-transmitting member is necessary based on a measurement value acquired when a state of no plasma generation in the chamber persists for a predetermined time period or longer. In this case, since the determination of whether or not maintenance is necessary is performed in a state in which the temperature of the chamber is sufficiently low (e.g., room temperature), the determination can be performed with high accuracy. The predetermined time period may be, for example, 30 minutes or more and 1 hour or less.

It is possible that the determination section obtains an estimated convergence value based on a plurality of measurement values acquired at different timings during a period in which a state of no plasma generation in the chamber persists, and whether or not maintenance of the light-transmitting member is necessary is determined based on the obtained estimated convergence value. Such an estimated convergence value is a value that is equal to or nearly equal to a measurement value obtained when a state of no plasma generation in the chamber persists for a predetermined time period or longer. That is, in the present configuration, determination of whether or not maintenance is necessary in a state in which the temperature of the chamber is sufficiently low can be performed in a pseudo manner within a time period shorter than the predetermined time period, thereby increasing the operating rate of the plasma processing apparatus. The number of the measurement values used for obtaining the estimated convergence value is not particularly limited, and may be, for example, two or more and five or less. For example, the estimated convergence value may be obtained based on an approximate temperature curve obtained by plotting a plurality of measurement values or may be obtained by applying a plurality of measurement values to a cooling characteristic of the plasma processing apparatus that is prespecified experimentally or analytically.

### (Plasma Processing Method)

The plasma processing method according to the present disclosure may be carried out by the above-described plasma processing apparatus but can also be carried out by a plasma processing apparatus that does not include the determination section. The plasma processing method is a method carried out by a plasma processing apparatus including the above-described chamber, the above-described plasma generation section, the above-described stage, and the above-described sensor, and includes a determination step.

In the determination step, whether or not maintenance of a light-transmitting member is necessary is determined based on a measurement value output by the sensor. When it is determined that maintenance of the light-transmitting member is necessary in the determination of necessity or unnecessity, appropriate plasma processing can be continued by performing maintenance of the light-transmitting member.

In the determination step, whether or not maintenance of the light-transmitting member is necessary may be determined based on a measurement value acquired when no plasma is generated in the chamber. In this case, whether or not maintenance of the light-transmitting member is necessary can be determined further more easily.

In the determination step, whether or not maintenance of the light-transmitting member is necessary may be determined based on a measurement value acquired when the substrate is not placed on the stage. In this case, whether or not maintenance of the light-transmitting member is necessary can be easily determined without moving the substrate into the chamber.

In the determination step, whether or not maintenance of the light-transmitting member is necessary may be determined based on a measurement value acquired when the substrate is placed on the stage. In this case, for example, preparation of a substrate particularly suitable for determining whether or not maintenance of the light-transmitting member is necessary makes it possible to improve determination accuracy.

In the determination step, whether or not maintenance of the light-transmitting member is necessary may be determined based on a measurement value acquired when a state of no plasma generation in the chamber persists for a predetermined time period or longer. In this case, since determination of whether or not maintenance is necessary is performed in a state in which the temperature of the chamber is sufficiently low (e.g., room temperature), the determination can be performed with high accuracy.

In the determination step, it is possible that an estimated convergence value is obtained based on a plurality of measurement values acquired at different timings during a period in which a state of no plasma generation in the chamber persists and whether or not maintenance of the light-transmitting member is necessary is determined based on the obtained estimated convergence value. In this configuration, determination of whether or not maintenance is necessary in a state in which the temperature of the chamber is sufficiently low can be performed in a pseudo manner within a time period shorter than the predetermined time period. Thus, the operation rate of the plasma processing apparatus can be increased.

As described above, according to the present disclosure, use of the measurement value output from the sensor can make it possible to determine whether or not maintenance of the light-transmitting member is necessary due to contamination. Further, according to the present disclosure, an appropriate plasma processing can be continued by performing maintenance of the light-transmitting member in a timely manner.

Hereinafter, examples of the plasma processing apparatus and the plasma processing method according to the present disclosure will be described in detail with reference to the accompanying drawings. The above-described elements of configuration and step can be applied to the elements of configuration and step of the exemplary plasma processing apparatus and plasma processing method described below. The elements of configuration and steps of the exemplary plasma processing apparatus and plasma processing method described below can be altered based on the above description. Further, the matters described below may be applied to the above-described embodiment. Among the elements of configuration and steps of the exemplary plasma processing apparatus and plasma processing method described below, an element of configuration or a step that is not essential to the plasma processing apparatus or the plasma processing method according to the present disclosure may be omitted. It should be noted that the drawings indicated below are schematic and do not accurately reflect the shape or number of actual members.

<<First Embodiment>>

The following describes a first embodiment of the present disclosure. Hereinafter, the configuration of a plasma processing apparatus 10 of the present embodiment will be described first, and then the plasma processing method of the present embodiment will be described.

### (Plasma Processing Apparatus)

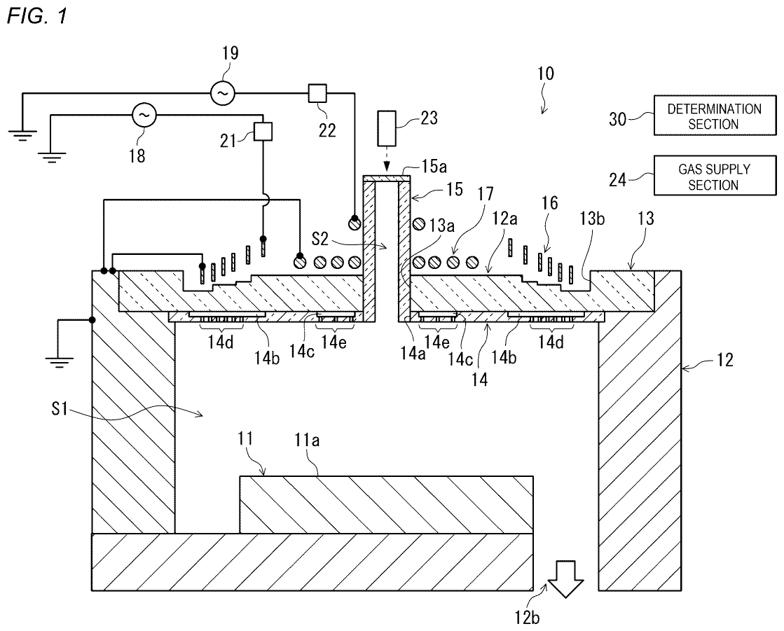

The plasma processing apparatus 10 of the present embodiment is an apparatus for performing plasma processing on a substrate (e.g., a semiconductor substrate) as an object to be processed. The plasma processing apparatus 10 of the present embodiment is a plasma dicer but is not limited thereto. As illustrated in FIG. 1, the plasma processing apparatus 10 includes a stage 11, a chamber 12, a first dielectric member 13, a cover 14, a second dielectric member 15, a first induction coil 16, a second induction coil 17, a first high-frequency power supply 18, a second high-frequency power supply 19, a sensor 23, a gas supply section 24, and a determination section 30.

The stage 11 is an element of configuration on which the substrate (not illustrated) is to be placed. The stage 11 has a horizontal placement surface 11a on which a substrate is to be placed. The stage 11 has a flow path (not illustrated) through which a refrigerant for cooling the substrate flows during the plasma processing. The stage 11 includes an electrostatic chuck mechanism (not illustrated) for chucking the substrate. The stage 11 includes a lower electrode (not illustrated) to which high-frequency power is applied.

The chamber 12 houses the stage 11 and has a first opening 12a at the top. The chamber 12 is formed in a hollow cylindrical shape but is not limited thereto. The first opening 12a opens upward. The chamber 12 is positioned around the outer periphery of the stage 11 and has an exhaust port 12b for exhausting a feed gas used in the plasma processing. A non-illustrated exhaust system is connected to the exhaust port 12b. The chamber 12 is constituted of a conductive member (e.g., metal) and is grounded. The first opening 12a is an example of the opening.

The first dielectric member 13 blocks a large part of the first opening 12a to define a first space S1 in the chamber 12 and has a second opening 13a. The first dielectric member 13 is formed in a horizontally extending plate shape. The first space S1 is a space in which the stage 11 is positioned. The second opening 13a passes through the first dielectric member 13 vertically. The second opening 13a is located in the central part of the first dielectric member 13. The first dielectric member 13 has a recess 13b on the upper surface thereof. The first dielectric member 13 is constituted of quartz but is not limited thereto.

The cover 14 is provided so as to cover the lower surface of the first dielectric member 13. The cover 14 has a first gas introduction path 14b through which the feed gas is supplied to a region of the first space S1 that is opposite the first induction coil 16, and a second gas introduction path 14c through which the feed gas is supplied to a region of the first space S1 that is opposite the second induction coil 17. The first gas introduction path 14b and the second gas introduction path 14c are each constituted as a groove or a recess formed on the upper surface of the cover 14. The first gas introduction path 14b communicates with the outside of the chamber 12 and communicates with the first space S1 via first gas holes 14d. The second gas introduction path 14c communicates with the outside of the chamber 12 and communicates with the first space S1 via second gas holes 14e. The first gas holes 14d and the second gas holes 14e are spaced apart from each other in the circumferential direction. The first gas holes 14d and the second gas holes 14e are arranged at intervals in the radial directions (the left-right direction in FIG. 1). The first gas introduction path 14b and the second gas introduction path 14c are each formed between the cover 14 and the first dielectric member 13. The feed gas is supplied to the first gas introduction path 14b and the second gas introduction path 14c from the gas supply section 24. The cover 14 has a third opening 14a overlapping with the second opening 13a. The third opening 14a is located in the central part of the cover 14. The cover 14 is constituted of aluminum nitride but is not limited thereto.

The second dielectric member 15 defines a second space S2 that communicates with the first space S1 via the second opening 13a and the third opening 14a and that extends above the first dielectric member 13. The second dielectric member 15 is fitted to the second opening 13a and the third opening 14a. The second dielectric member 15 is formed in a cylindrical shape extending vertically. The second dielectric member 15 is constituted of aluminum nitride but is not limited thereto.

The second dielectric member 15 includes a dielectric window 15a for optical measurement at the top. The dielectric window 15a blocks a part of the central region of the first opening 12a. The dielectric window 15a transmits the infrared rays and the like emitted from the stage 11 or the substrate placed on the stage 11. The dielectric window 15a may be integral with or separate from the cylindrical part of the second dielectric member 15. The dielectric window 15a is constituted of calcium fluoride but is not limited thereto. The dielectric window 15a is an example of the transmission member.

The first induction coil 16 extends from the central side toward the outer peripheral side of the first dielectric member 13 above the first dielectric member 13 and generates plasma for substrate processing. The first induction coil 16 is constituted of one or more conductors each extending spirally in the circumferential direction. A part of the first induction coil 16 located on the outer peripheral side is positioned inside the recess 13b formed on the first dielectric member 13. The first induction coil 16 receives high-frequency power from the first high-frequency power supply 18 to generate a magnetic field. The generated magnetic field acts on the feed gas in the first space S1 via the first dielectric member 13, thereby generating plasma.

The second induction coil 17 is provided so as to surround the second dielectric member 15 and generates plasma for substrate processing. The second induction coil 17 has a part extending in the vertical direction along the second dielectric member 15 and a part extending in the horizontal direction along the first dielectric member 13. The former has a helical shape extending in the vertical direction, while the latter has a spiral shape (coiled shape) extending in the horizontal direction. The second induction coil 17 is positioned inward of the first induction coil 16. The second induction coil 17 receives high-frequency power from the second high-frequency power supply 19 to generate a magnetic field. The generated magnetic field acts on the feed gas in either or both the first space S1 and the second space S2 via the second dielectric member 15, thereby generating plasma.

The first high-frequency power supply 18 supplies high-frequency power (e.g., AC power at 3 to 30 MHz) to the first induction coil 16. The first high-frequency power supply 18 is connected to one end of the first induction coil 16 via a first matching unit 21 such as a variable capacitor. The other end of the first induction coil 16 is grounded via the chamber 12 which is conductive.

The second high-frequency power supply 19 supplies high-frequency power (e.g., AC power at 3 to 30 MHz) to the second induction coil 17. The second high-frequency power supply 19 is connected to one end of the second induction coil 17 via a second matching unit 22 such as a variable capacitor. The other end of the second induction coil 17 is grounded via the chamber 12 which is conductive.

The frequency of the power (power applied to the first induction coil 16) of the first high-frequency power supply 18 and the frequency of the power (power applied to the second induction coil 17) of the second high-frequency power supply 19 are different from each other. Note that these frequencies may be equal to each other. Alternatively, a single high-frequency power supply may be provided, instead of the first high-frequency power supply 18 and the second high-frequency power supply 19, to distribute the power thereof to the first induction coil 16 and the second induction coil 17.

The first induction coil 16, the second induction coil 17, the first high-frequency power supply 18, and the second high-frequency power supply 19 constitute the plasma generation section in the present embodiment.

The sensor 23 is provided above the dielectric window 15a and receives the infrared rays emitted from the stage 11 or the substrate placed on the stage 11. The sensor 23 outputs a measurement value corresponding to the intensity of the received infrared rays (hereinafter, also referred to simply as measurement value). Information about the measurement value is sent to the determination section 30 through wired or wireless communication.

The gas supply section 24 supplies the feed gas of plasma into the chamber 12. The gas supply section 24 is connected to the first gas introduction path 14b and the second gas introduction path 14c via a non-illustrated gas pipe. The gas supply section 24 is configured to be able to switch the type of the feed gas to be supplied so that the type of plasma generated in the chamber 12 is switchable.

The determination section 30 includes an arithmetic unit and a storage device that stores therein programs (e.g., a program for executing the plasma processing method of the present embodiment) executable by the arithmetic unit. The determination section 30 determines whether or not maintenance of the dielectric window 15a is necessary based on a measurement value T output by the sensor 23.

The determination section 30 of the present embodiment determines whether or not maintenance of the dielectric window 15a is necessary based on a measurement value T acquired when no plasma is generated in the chamber 12. In addition, the determination section 30 determines whether or not maintenance of the dielectric window 15a is necessary based on a measurement value T acquired when the substrate is placed on the stage 11.

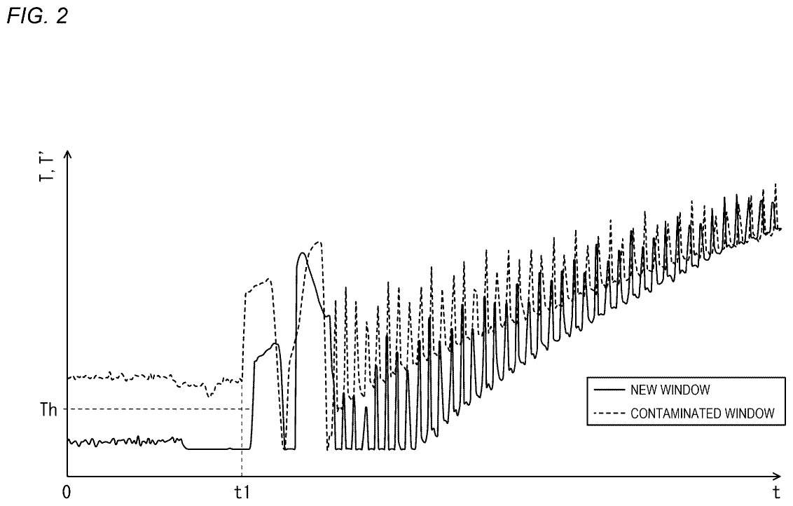

FIG. 2 is a graph showing examples of measurement values T of the sensor 23 before and after plasma processing is started. In this graph, the horizontal axis presents the processing time and the vertical axis presents the measurement values T. The solid line indicates a measurement value T when a new (or non-contaminated) dielectric window 15a is used, and the broken line indicates a measurement value T′ when a contaminated dielectric window 15a is used. This graph shows the transition of the measurement values T, T′ when the plasma processing (specifically, substrate chucking and subsequent etching) is started at a time t1. As can be understood from the graph, the difference between the measurement value T for the case with the new dielectric window 15a and the measurement value T′ for the case with the contaminated dielectric window 15a is larger before the plasma processing is started than during the plasma processing (in particular, the timing at which the plasma processing has progressed to some extent). The determination section 30 of the present embodiment compares the measurement value T with a predetermined threshold value Th before the plasma processing is started, and determines that maintenance of the dielectric window 15a is necessary when the measurement value T exceeds the threshold value Th. When the measurement value T is equal to or less than the threshold value Th before the plasma processing is started by contrast, the determination section 30 may determine that maintenance of the dielectric window 15a is not necessary.

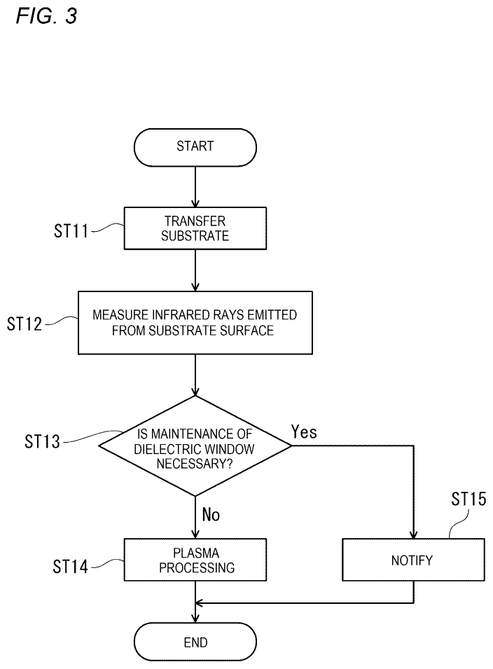

(Plasma Processing Method) The plasma processing method of the present embodiment is executable, for example, by the plasma processing apparatus 10 of the present embodiment, and includes a transfer step ST11, a measurement step ST12, a determination step ST13, a plasma processing step ST14, and a notification step ST15 as depicted in FIG. 3.

In the transfer step ST11, the substrate is transferred into the chamber 12 and placed on the stage 11. The above transfer and placement may be performed, for example, by a robot equipped with an end effector capable of holding a substrate.

In the measurement step ST12, the sensor 23 receives the infrared rays emitted from the substrate placed on the stage 11 through the dielectric window 15a, and outputs a measurement value T corresponding to the intensity of the received infrared rays.

In the determination step ST13, the determination section 30 determines whether or not maintenance of the dielectric window 15a is necessary based on the measurement value T. If it is determined that maintenance of the dielectric window 15a is not necessary (“No” in the determination step ST13), the process proceeds to the plasma processing step ST14. If it is determined that maintenance of the dielectric window 15a is necessary (“Yes” in the determination step ST13) by contrast, the process proceeds to the notification step ST15.

In the plasma processing step ST14, plasma processing is performed on the substrate, and the plasma processing method of the present embodiment ends then.

In the notification step ST15, the determination section 30 notifies the operator of the plasma processing apparatus 10 that maintenance of the dielectric window 15a is necessary. Then, the plasma processing method of the present embodiment ends. Note that the method of the notification is not particularly limited, and the notification may be performed, for example, visually using a monitor or a lamp or audibly using a speaker.

### Second Embodiment

The following describes a second embodiment of the present disclosure. A plasma processing apparatus 10 and a plasma processing method of the present embodiment differ from those of the first embodiment in that the infrared rays emitted from the stage 11 are used to determine whether or not maintenance is necessary. Hereinafter, differences from the first embodiment will be mainly described.

### (Plasma Processing Apparatus)

The determination section 30 of the plasma processing apparatus 10 of the present embodiment determines whether or not maintenance of the dielectric window 15a is necessary, based on a measurement value T acquired when the substrate is not placed on the stage 11. In addition, the determination section 30 determines whether or not maintenance of the dielectric window 15a is necessary based on a measurement value T acquired when a state of no plasma generation in the chamber 12 persists for a predetermined time period or longer.

### (Plasma Processing Method)

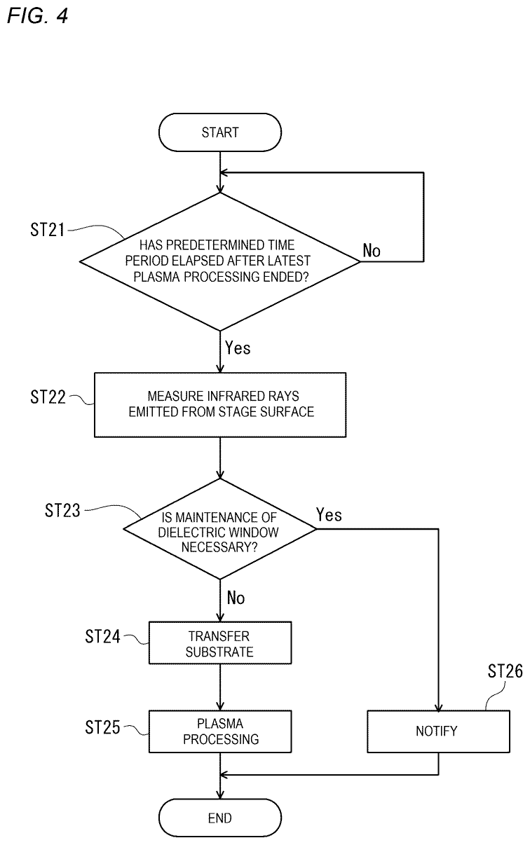

As depicted in FIG. 4, the plasma processing method of the present embodiment includes a standby step ST21, a measurement step ST22, a determination step ST23, a transfer step ST24, a plasma processing step ST25, and a notification step ST26.

In the standby step ST21, it is determined whether or not a predetermined time period has elapsed after the latest plasma processing ended. If the determination result is “Yes”, the process proceeds to the measurement step ST22. If the determination result is “No” by contrast, the standby step ST21 is repeated.

In the measurement step ST22, the sensor 23 receives the infrared rays emitted from the stage 11 through the dielectric window 15a, and outputs a measurement value T corresponding to the intensity of the received infrared rays.

In the determination step ST23, the determination section 30 determines whether or not maintenance of the dielectric window 15a is necessary based on the measurement value T. If it is determined that maintenance of the dielectric window 15a is not necessary (“No” in the determination step ST23), the process proceeds to the transfer step ST24. If it is determined that maintenance of the dielectric window 15a is necessary (“Yes” in the determination step ST23) by contrast, the process proceeds to the notification step ST26.

In the transfer step ST24, the substrate is transferred into the chamber 12 and placed on the stage 11. The above transfer and placement may be performed, for example, by a robot equipped with an end effector capable of holding a substrate.

In the plasma processing step ST25, plasma processing is performed on the substrate. Then, the plasma processing method of the present embodiment ends.

In the notification step ST26, the determination section 30 notifies the operator of the plasma processing apparatus 10 that maintenance of the dielectric window 15a is necessary. Then, the plasma processing method of the present embodiment ends. Note that the method of the notification is not particularly limited, and the notification may be performed, for example, visually using a monitor or a lamp or audibly using a speaker.

### Third Embodiment

The following describes a third embodiment of the present disclosure. A plasma processing apparatus 10 and a plasma processing method of the present embodiment differ from those of the first embodiment in that an estimated convergence value Te obtained from a plurality of measurement values T is used in determination of whether or not maintenance is necessary. Hereinafter, differences from the first embodiment will be mainly described.

### (Plasma Processing Apparatus)

The determination section 30 of the plasma processing apparatus 10 of the present embodiment obtains an estimated convergence value Te based on a plurality of measurement values T acquired at different timings during a period in which the state of no plasma generation in the chamber 12 persists, and determines whether or not maintenance of the dielectric window 15a is necessary based on the obtained estimated convergence value Te.

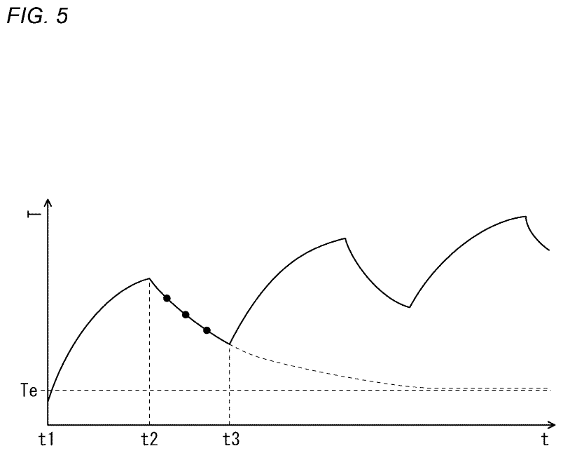

FIG. 5 is a graph showing an example of the measurement value T of the sensor 23 during plasma processing. In this graph, the horizontal axis presents the processing time, and the vertical axis presents the measurement value T. The solid line indicates the measurement value, and the broken line indicates an estimated value on the assumption that no plasma is generated. The solid line in this graph indicates the transition of the measurement value T when plasma generation in the chamber 12 is started at a time t1, the plasma generation is suspended at a time t2, the plasma generation is resumed at a time t3, and the same processes are repeated thereafter. By contrast, the broken line indicates the estimated value on the assumption that the plasma processing is completed as-is without resuming the plasma generation at the time t3. As shown in the graph, the estimated value is asymptotic to the estimated convergence value Te obtained by any appropriate method based on a plurality of measurement values T (indicated by dots in FIG. 5) acquired at different timings between the time t2 and the time t3. The determination section 30 of the present embodiment is configured to determine whether or not maintenance of the dielectric window 15a is necessary by comparing the estimated convergence value Te with the aforementioned predetermined threshold value Th.

### (Plasma Processing Method)

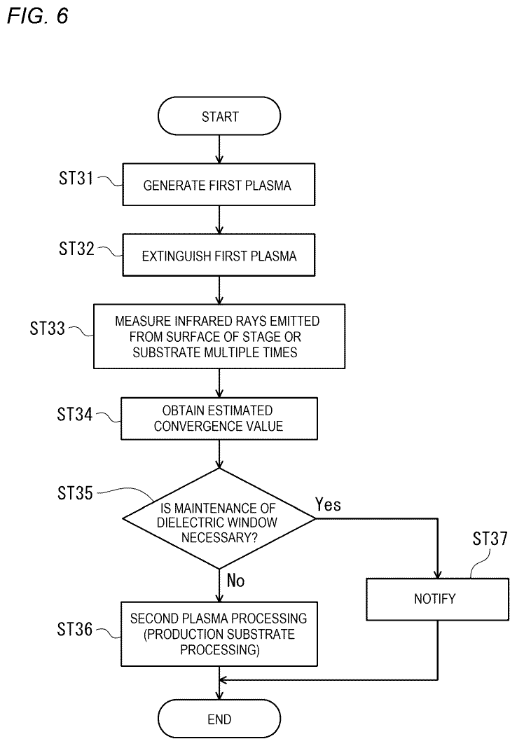

As depicted in FIG. 6, the plasma processing method of the present embodiment includes a first plasma generation step ST31, a first plasma extinguishment step ST32, a measurement step ST33, an estimation step ST34, a determination step ST35, a second plasma processing step ST36, and a notification step ST37.

Before the first plasma generation step 31, a move-in step of transferring the substrate into the chamber 12 and placing the substrate on the stage 11 may be performed. When performing the move-in step, a move-out step of transferring the substrate out of the chamber 12 may be performed after the first plasma extinguishment step ST32. The above move-in, placement, and move-out may be performed, for example, by a robot equipped with an end effector capable of holding a substrate. The substrate transferred in the move-in step may be a substrate for production or a dummy substrate such as a silicon substrate.

In the first plasma generation step ST31, the plasma generation section generates first plasma in the chamber 12. The first plasma may be cleaning plasma used for performing cleaning in the chamber 12 before production starts, for example. Alternatively, the first plasma may be seasoning plasma used for performing seasoning to stabilize the atmosphere in the chamber 12, for example. The first plasma may be second plasma used for performing plasma processing on a production substrate described later, for example.

In the first plasma extinguishment step ST32, the plasma generation section extinguishes the first plasma (or generation of the first plasma is suspended).

In the measurement step ST33, the sensor 23 receives the infrared rays emitted from the stage 11 or the substrate placed on the stage 11 through the dielectric window 15a during a period in which a state of no plasma generation in the chamber 12 persists, and outputs measurement values T corresponding to the intensities of the received infrared rays a plurality of times at different timings.

In the estimation step ST34, the determination section 30 obtains an estimated convergence value Te based on the plurality of measurement values T by any appropriate method.

In the determination step ST35, the determination section 30 determines whether or not maintenance of the dielectric window 15a is necessary based on the obtained estimated convergence value Te. If it is determined that maintenance of the dielectric window 15a is not necessary (“No” in the determination step ST35), the process proceeds to the second plasma processing step ST36. If it is determined that maintenance of the dielectric window 15a is necessary (“Yes” in the determination step ST35) by contrast, the process proceeds to the notification step ST37.

In the second plasma processing step ST36, the production substrate is transferred into the chamber 12. Thereafter, the plasma generation section generates the second plasma in the chamber 12 to perform plasma processing on the production substrate. The second plasma may be etching plasma for production substrate etching, for example.

In the notification step ST37, the determination section 30 notifies the operator of the plasma processing apparatus 10 that maintenance of the dielectric window 15a is necessary. Then, the plasma processing method of the present embodiment ends. Note that the method of the notification is not particularly limited, and the notification may be performed visually using a monitor or a lamp or audibly using a speaker, for example.

### Supplemental Remarks

According to the above description of the embodiments, the following techniques are disclosed.

### (Technique 1)

A plasma processing apparatus including:
a chamber having an opening;
a plasma generation section that generates plasma in the chamber;
a light-transmitting member that blocks at least a part of the opening and that transmits infrared rays;
a stage that is provided in the chamber and on which a substrate is to be placed;
a sensor that receives infrared rays emitted from the stage or the substrate placed on the stage through the light-transmitting member and outputs a measurement value corresponding to an intensity of the received infrared rays; and
a determination section that determines whether or not maintenance of the light-transmitting member is necessary based on the measurement value.

### (Technique 2)

The plasma processing apparatus according to Technique 1, wherein the determination section determines whether or not maintenance of the light-transmitting member is necessary based on the measurement value, the measurement value being acquired when no plasma is generated in the chamber.

### (Technique 3)

The plasma processing apparatus according to Technique 2, wherein the determination section determines whether or not maintenance of the light-transmitting member is necessary based on the measurement value, the measurement value being acquired when the substrate is not placed on the stage.

### (Technique 4)

The plasma processing apparatus according to Technique 2, wherein the determination section determines whether or not maintenance of the light-transmitting member is necessary based on the measurement value, the measurement value being acquired when the substrate is placed on the stage.

### (Technique 5)

The plasma processing apparatus according to Technique 3 or 4, wherein the determination section determines whether or not maintenance of the light-transmitting member is necessary based on the measurement value, the measurement value being acquired when a state of no plasma generation in the chamber persists for a predetermined time period or longer.

### (Technique 6)

The plasma processing apparatus according to Technique 3 or 4, wherein the determination section obtains an estimated convergence value based on a plurality of the measurement values and determines whether or not maintenance of the light-transmitting member is necessary based on the obtained estimated convergence value, the plurality of measurement values being acquired at different timings during a period in which state of no plasma generation in the chamber persists.

### (Technique 7)

A plasma processing method carried out by a plasma processing apparatus including:
a chamber having an opening;
a plasma generation section that generates plasma in the chamber;
a light-transmitting member that blocks at least a part of the opening and that transmits infrared rays;
a stage that is provided in the chamber and on which a substrate is to be placed; and
a sensor that receives infrared rays emitted from the stage or the substrate placed on the stage through the light-transmitting member and outputs a measurement value corresponding to an intensity of the received infrared rays, the method including
a determination step of determining whether or not maintenance of the light-transmitting member is necessary based on the measurement value.

### (Technique 8)

The plasma processing method according to Technique 7, wherein in the determination step, whether or not maintenance of the light-transmitting member is necessary is determined based on the measurement value, the measurement value being acquired when no plasma is generated in the chamber.

### (Technique 9)

The plasma processing method according to Technique 8, wherein in the determination step, whether or not maintenance of the light-transmitting member is necessary is determined based on the measurement value, the measurement value being acquired when the substrate is not placed on the stage.

### (Technique 10)

The plasma processing method according to Technique 8, wherein in the determination step, whether or not maintenance of the light-transmitting member is necessary is determined based on the measurement value, the measurement value being acquired when the substrate is placed on the stage.

### (Technique 11)

The plasma processing method according to Technique 9 or 10, wherein in the determination step, whether or not maintenance of the light-transmitting member is necessary is determined based on the measurement value, the measurement value being acquired when a state of no plasma generation in the chamber persists for a predetermined time period or longer.

### (Technique 12)

The plasma processing method according to Technique 9 or 10, wherein in the determination step, an estimated convergence value is obtained based on a plurality of the measurement values acquired at different timings during a period in which a state of no plasma generation in the chamber persists, and whether or not maintenance of the light-transmitting member is necessary is determined based on the obtained estimated convergence value.

### INDUSTRIAL APPLICABILITY

The present disclosure can be utilized for plasma processing apparatuses and plasma processing methods.

### REFERENCE NUMERALS

10: plasma processing apparatus
11: stage
11a: placement surface
12: chamber
12a: first opening (opening)
12b: exhaust port
13: first dielectric member
13a: second opening
13b: recess
14: cover
14a: third opening
14b: first gas introduction passage
14c: second gas introduction path
14d: first gas hole
14e: second gas hole
15: second dielectric member
15a: dielectric window (light-transmitting member)
16: first induction coil (plasma generation section)
17: second induction coil (plasma generation section)
18: first high-frequency power supply (plasma generation section)
19: second high-frequency power supply (plasma generation section)
21: first matching unit
22: second matching unit
23: sensor
24: gas supply section
30: determination section
S1: first space
S2: second space
T: measurement value
T′: measurement value where dielectric window is contaminated
Te: estimated convergence value
Th: threshold value

What is claimed is:

1. A plasma processing apparatus comprising:
a chamber having an opening;
a plasma generation section that generates plasma in the chamber;
a light-transmitting member that blocks at least a part of the opening and that transmits infrared rays;
a stage that is provided in the chamber and on which a substrate is to be placed;
a sensor that receives infrared rays emitted from the stage or the substrate placed on the stage through the light-transmitting member and outputs a measurement value corresponding to an intensity of the received infrared rays; and
a determination section that determines whether or not maintenance of the light-transmitting member is necessary based on the measurement value.

2. The plasma processing apparatus according to claim 1,
wherein the determination section determines whether or not maintenance of the light-transmitting member is necessary based on the measurement value, the measurement value being acquired when no plasma is generated in the chamber.

3. The plasma processing apparatus according to claim 2,
wherein the determination section determines whether or not maintenance of the light-transmitting member is necessary based on the measurement value, the measurement value being acquired when the substrate is not placed on the stage.

4. The plasma processing apparatus according to claim 2,
wherein the determination section determines whether or not maintenance of the light-transmitting member is necessary based on the measurement value, the measurement value being acquired when the substrate is placed on the stage.

5. The plasma processing apparatus according to claim 3,
wherein the determination section determines whether or not maintenance of the light-transmitting member is necessary based on the measurement value, the measurement value being acquired when a state of no plasma generation in the chamber persists for a predetermined time period or longer.

6. The plasma processing apparatus according to claim 4,
wherein the determination section determines whether or not maintenance of the light-transmitting member is necessary based on the measurement value, the measurement value being acquired when a state of no plasma generation in the chamber persists for a predetermined time period or longer.

7. The plasma processing apparatus according to claim 3,
wherein the determination section obtains an estimated convergence value based on a plurality of the measurement values and determines whether or not maintenance of the light-transmitting member is necessary based on the obtained estimated convergence value, the plurality of measurement values being acquired at different timings during a period in which state of no plasma generation in the chamber persists.

8. The plasma processing apparatus according to claim 4,
wherein the determination section obtains an estimated convergence value based on a plurality of the measurement values and determines whether or not maintenance of the light-transmitting member is necessary based on the obtained estimated convergence value, the plurality of measurement values being acquired at different timings during a period in which state of no plasma generation in the chamber persists.

9. A plasma processing method carried out by a plasma processing apparatus including:
a chamber having an opening;
a plasma generation section that generates plasma in the chamber;
a light-transmitting member that blocks at least a part of the opening and that transmits infrared rays;
a stage that is provided in the chamber and on which a substrate is to be placed; and
a sensor that receives infrared rays emitted from the stage or the substrate placed on the stage through the light-transmitting member and outputs a measurement value corresponding to an intensity of the received infrared rays, the method comprising
a determination step of determining whether or not maintenance of the light-transmitting member is necessary based on the measurement value.

10. The plasma processing method according to claim 9, wherein in the determination step, whether or not maintenance of the light-transmitting member is necessary is determined based on the measurement value, the measurement value being acquired when no plasma is generated in the chamber.

11. The plasma processing method according to claim 10,
wherein in the determination step, whether or not maintenance of the light-transmitting member is necessary is determined based on the measurement value, the measurement value being acquired when the substrate is not placed on the stage.

12. The plasma processing method according to claim 10,
wherein in the determination step, whether or not maintenance of the light-transmitting member is necessary is determined based on the measurement value, the measurement value being acquired when the substrate is placed on the stage.

13. The plasma processing method according to claim 11,
wherein in the determination step, whether or not maintenance of the light-transmitting member is necessary is determined based on the measurement value, the measurement value being acquired when a state of no plasma generation in the chamber persists for a predetermined time period or longer.

14. The plasma processing method according to claim 12,
wherein in the determination step, whether or not maintenance of the light-transmitting member is necessary is determined based on the measurement value, the measurement value being acquired when a state of no plasma generation in the chamber persists for a predetermined time period or longer.

15. The plasma processing method according to claim 11,
wherein in the determination step, an estimated convergence value is obtained based on a plurality of the measurement values acquired at different timings during a period in which a state of no plasma generation in the chamber persists, and whether or not maintenance of the light-transmitting member is necessary is determined based on the obtained estimated convergence value.

16. The plasma processing method according to claim 12,
wherein in the determination step, an estimated convergence value is obtained based on a plurality of the measurement values acquired at different timings during a period in which a state of no plasma generation in the chamber persists, and whether or not maintenance of the light-transmitting member is necessary is determined based on the obtained estimated convergence value.
